(19) United States
(12) Patent Application Publication
(10) Pub. No.: US 2011/0050506 A1
(43) Pub. Date: Mar. 3, 2011

(54) ANTENNA ARRANGEMENT

(75) Inventor: WOLFGANG DOERR, WIEHL (DE)

(73) Assignee: DELPHI TECHNOLOGIES, INC., TROY, MI (US)

(21) Appl. No.: 12/868,113

(22) Filed: Aug. 25, 2010

(30) Foreign Application Priority Data
Aug. 27, 2009 (EP) 09011000.8

(51) Int. Cl. H01Q 1/38; H05K 3/00

(52) U.S. Cl. 343/700 MS; 29/601; 29/852

(57) ABSTRACT

The present invention relates to an antenna arrangement with a printed circuit board, which has an upper side and a lower side, and an antenna supported by the printed circuit board, in particular ring antenna, which comprises at least one electrically conductive antenna section which is arranged on a narrow side of the printed circuit board adjoining the upper side and/or the lower side. The invention also relates to a process for producing an antenna arrangement which comprises a printed circuit board with an upper side and a lower side and an antenna supported by the printed circuit board, in which process for forming at least one antenna section, an electrically conductive material is attached to a narrow side of the printed circuit board which adjoins the upper side and/or the lower side.

### TECHNICAL FIELD

The present invention relates to an antenna arrangement with a substrate/printed circuit board and an antenna supported by the substrate/printed circuit board.

### BACKGROUND OF THE INVENTION

Such antenna arrangements are known in principle and are used, for example as transmitting antennae in-hand transmitters or electronic keys with which, for example motor vehicles may be locked and unlocked by remote control or garage doors may be opened and closed.

The known antennae arrangements prove to be disadvantageous inasmuch as they have a comparatively low antenna efficiency. That is, the transmission power broadcast by the antenna which can be used is relatively low compared to the power input of the antenna which is necessary therefor.

In the known antenna arrangements this generally leads to a low range and to a high energy requirement of the antenna or to a correspondingly low battery service life.

### SUMMARY OF THE INVENTION

The object of the present invention is therefore to provide an antenna arrangement of the type mentioned in the introduction which has an increased antenna efficiency.

To achieve this object, an antenna arrangement having the features of the claims is provided.

The antenna arrangement of the invention comprises a substrate such as a printed circuit board, which has an upper side and a lower side, and an antenna supported by the printed circuit board, in particular ring antenna, which comprises at least one electrically conductive antenna section, which is arranged on a narrow side of the printed circuit board adjoining the upper side and/or the lower side.

According to the invention it has been recognised that the efficiency of the antenna arrangement is impaired in particular by power losses in the conductive track of the antenna and by dielectric losses in the dielectric material of the printed circuit board. Due to the arrangement of an antenna section on the narrow side, the power losses occurring during operation of the antenna can be reduced and the antenna efficiency thus increased.

The cause of the problems of high power losses is not least the skin effect, which is particularly pronounced at frequencies which are suitable for operation of the antenna arrangement. The skin effect designates the phenomenon that eddy currents counteract an alternating current flowing in the interior of a conductor increasingly at high frequencies and which are induced by the alternating current in the interior of the conductor and thus reduce the net current flow so that the current flow is displaced from the centre of the conductor to the edge of the conductor. Consequently, at high frequencies essentially only the edge of the conductor contributes to the current power, and the effective resistance of the conductor is increased.

In addition there is the fact that a conductor arranged on the upper side or lower side of the printed circuit board conducts the current only less efficiently in that edge region in which it is in contact with the upper side or lower side, because the surface of the printed circuit board and hence also that of the conductor in this edge region conventionally have a high roughness and the current path in this region is extended accordingly.

The dielectric losses are produced in the printed circuit board supporting the antenna and thus depend on the dielectric loss properties of the materials forming the printed circuit board. Within the framework of the invention, the printed circuit board supporting the antenna preferably consists completely of electrically non-conductive, dielectric material. The printed circuit board may be laminated, for example from several dielectric layers.

The design according to the invention of a conductive antenna section on a narrow side of the printed circuit board provides an electric current path with good current-conduction properties and thus reduces the power losses of the antenna which occur.

One advantage of a conductive antenna section attached to a narrow side is thus that the antenna section itself does not require any space on the upper side and or the lower side. Hence, a relatively large electrically conductive antenna section may also be realised with low space supply on the upper side and lower side of the printed circuit board and hence increased conductivity of the antenna may be achieved.

A narrow-sided antenna section is particularly advantageous when the antenna is a ring antenna and has a current path which runs at least essentially annularly in the plane of the printed circuit board. A narrow-sided antenna section has here at least approximately the shape of a jacket segment, which leads to a particularly good emission characteristic and contributes to increased antenna efficiency.

As a result the antenna arrangement of the invention thus has an improved antenna efficiency, as a result of which in the end not only the antenna range is increased, but also the energy requirement is reduced.

Advantageous embodiments of the invention are described in the sub-claims, the description and the drawings.

The conductive antenna section arranged on the narrow side preferably has a metallic material, in particular copper or gold. The conductive narrow-sided antenna section is preferably a metallic layer arranged on the narrow side and having essentially constant thickness, which is for example several 10 μm.

According to one embodiment, the narrow side of the printed circuit board adjoins the upper side and/or the lower side of the printed circuit board. The narrow side may thus extend essentially vertically to the upper side or lower side of the printed circuit board. It is preferred if the narrow side extends from the upper side to the lower side of the printed circuit board and hence thus through the printed circuit board. In this case the narrow side makes available a particularly large surface for the antenna section arranged on the narrow side.

The narrow side may define a hole of the printed circuit board extending through the printed circuit board and which is preferably designed to be elongated. Alternatively, the narrow side may form an outer side of the printed circuit board. If the narrow-sided antenna section adjoins a hole or an outer side of the printed circuit board, less dielectric printed circuit board material is present in the immediate surroundings of the narrow-sided antenna section, as a result of which the dielectric losses of the electromagnetic field generated by a current flowing in the narrow-sided antenna section are reduced. In addition, such narrow sides can be formed particularly simply, for example by holes being formed in the printed circuit board by a milling process or by the outer contour of the printed circuit board being cut to size accordingly by a milling process.

According to a further embodiment, the narrow-sided antenna section does not form a closed electrically conductive ring. If the narrow side, to which the antenna section is attached, defines a hole of the printed circuit board, the antenna section is preferably attached only to one part region of the narrow side defining the hole without forming a closed ring in the hole. Such a narrow-sided antenna section may be generated in simple manner by complete coating of a narrow side defining a hole with electrically conductive material and subsequent removal of undesirable electrically conductive material.

Although within the framework of the invention, an antenna arrangement can be conceived which has exclusively a narrow-sided antenna section and no upper-side or lower-side antenna sections, the antenna section arranged on the narrow side according to a preferred embodiment is connected to an antenna section running on the upper side and/or to an antenna section running on the lower side. By providing the narrow-sided antenna section in addition to an antenna section connected to the narrow-sided antenna section and running on the upper side and/or lower side, the conductivity of the entire arrangement is significantly increased. The narrow-sided antenna section may be connected along its at least approximately entire length to the antenna section running on the upper side or lower side.

According to a further embodiment, two narrow-sided antenna sections on opposite side of an antenna section running on the upper side or of an antenna section running on the lower side are connected to the latter. The two narrow-sided antenna sections and the upper-side or lower-side antenna section thus form two angles, in the apices of which higher currents may flow, as a result of which the conductivity of the antenna section as a whole is increased still further.

According to a further embodiment, the antenna section arranged on the narrow side extends through the printed circuit board and connects an antenna section arranged on the upper side of the printed circuit board to an antenna section arranged on the lower side of the printed circuit board. Due to this arrangement, likewise two antenna section angles are formed, in the apices of which higher currents may flow and which contribute to an increased antenna efficiency.

An upper-side and a lower-side antenna section are advantageously connected to one another by two opposing narrow-sided antenna sections. Four antenna section angles are formed in this manner and an even higher current flow and antenna efficiency achieved.

According to a further embodiment provision is made in that the antenna section arranged on the narrow side electrically bridges an interruption of a first antenna section running on the upper side or on the lower side of the printed circuit board. The narrow-sided antenna section may thus connect the first antenna section additionally to a second antenna section running on the lower side or upper side.

An interruption of the antenna section of the upper side or lower side of the printed circuit board may thus serve to accommodate other circuit parts attached to the upper side or lower side of the printed circuit board, such as for example a conductor track running through the interruption to connect various circuit parts or components.

Hence, the printed circuit board may support, apart from the antenna, still further circuit parts, which are produced for example in common process steps with the antenna, for example connection leads and connection surfaces for further circuit parts arranged on the printed circuit board.

Antenna sections arranged on the upper side and/or lower side of the printed circuit board may be formed in this case in a common process step with the further circuit parts, such as for example connection leads and connection surfaces. Such further circuit parts may belong, for example to an activation circuit which exposes the antenna attached to the printed circuit board to an activation signal, or, in the case of a receiving antenna, to a receiving and evaluation circuit. In the case of a transmitting antenna, the antenna is preferably activated at frequencies in the range between 300 and 1,000 MHz.

A further object of the invention is a process having the features of the process claims. The process of the invention may serve in particular for the production of an antenna arrangement of the type described above. The advantages illustrated above thus apply accordingly.

In the process of the invention, to form at least one antenna section, an electrically conductive material is attached to a narrow side of the printed circuit board, which adjoins the upper side and/or the lower side of the printed circuit board.

According to one embodiment, the narrow side of the printed circuit board is generated by removing printed circuit board material, in particular by forming an, in particular elongated, hole in the printed circuit board, for example by a drilling or milling process. Drilling and milling processes for printed circuit boards are known per se and may be effected in simple manner with available tools and machines.

Several holes along the required antenna conductor track for several narrow-sided antenna sections are advantageously generated in the printed circuit board. Known drilling or milling machines may generate such a plurality of holes with high precision and at high speed using an electronic layout, for example a CAD layout.

It is particularly preferred if the removal of printed circuit board material for generating the narrow side is effected in a common process step with the formation of holes for interconnections between circuit parts on the upper side and circuit parts on the lower side of the printed circuit board, so-called vias.

Due to the common generation of via holes and narrow side(s), the production process for the antenna arrangement is simplified by there being no need to carry out a separate process step for removing printed circuit board material for generating the narrow side(s). The via holes and the narrow side(s) may thus be produced in particular in one and the same tool machine without the printed circuit board having to be removed in between from the working region of the machine. The geometric data for drilling and/or milling for generating the narrow side(s) may thus be added simply to the layout data file for generating the via holes.

According to an advantageous embodiment, the electrically conductive material is attached to the narrow side by a deposition process, in particular by means of a galvanic process. By galvanic deposition processes, layers of electrically conductive material may be generated on a narrow side which have high quality, high electric conductivity and good adhesion to the printed circuit board material. Copper and/or gold is preferably deposited and particularly preferably a layer having at least approximately constant thickness is deposited, which may be for example between 30 and 100 μm.

It is particularly preferred if the narrow sides and the side walls, which define the via holes, are coated with electrically conductive material at the same time in a common deposition process, since a separate deposition process is thus not necessary on the narrow sides for generating the antenna sections.

Electrically conductive material attached to the narrow sides and/or printed circuit board material which is adjoined thereto is preferably subsequently removed in some regions, for example by a milling process.

Electrically conductive material not required can be eliminated in this manner, for example electrically conductive material which is facing away from the antenna section, or the weight and the space requirement of the printed circuit board can be reduced. In addition, dielectric losses can be reduced by the removal of printed circuit board material.

For example the narrow side may be generated by the formation of a hole in the printed circuit board and after metallisation of the narrow side, printed circuit board material may be removed which extends between the hole and an outer side of the printed circuit board so that the narrow side itself becomes the outer side of the printed circuit board. The outer contour of the printed circuit board is thus reduced by cutting to size until the narrow side becomes the outer side of the printed circuit board. This cutting-to-size of the printed circuit board towards the narrow side reduces the space requirement of the printed circuit board and the dielectric losses which occur. Since the narrow-sided antenna section extends at least in some regions along the outer contour of the printed circuit board, for preset size, in addition a maximum antenna length or a maximum antenna diameter is achieved.

### BRIEF DESCRIPTION OF THE DRAWINGS

The present invention is described below purely by way of example using an advantageous embodiment with reference to the attached drawings.

FIG. 1a shows a printed circuit board arrangement after drilling via holes;

FIG. 1b shows a cross-sectional view along the line A-A′ of FIG. 1a on an enlarged scale;

FIG. 2a shows the arrangement of FIG. 1 after milling elongated holes;

FIG. 2b shows a cross-sectional view along the line A-A′ of FIG. 2a on an enlarged scale;

FIG. 3a shows the arrangement of FIG. 2 after coating of the holes with conductive material;

FIG. 3b shows a cross-sectional view along the line A-A′ of FIG. 3a on an enlarged scale;

FIG. 4a shows the arrangement of FIG. 3 after structuring of conductor tracks;

FIG. 4b shows a cross-sectional view along the line A-A′ of FIG. 4a on an enlarged scale;

FIG. 4c shows a rear-side view of the arrangement of FIG. 4a;

FIG. 5 shows a cut-to-size trajectory, along which the printed circuit board arrangement of FIG. 4 is cut to size on a reduced scale;

FIG. 6a shows an antenna arrangement of the invention which has been produced by the process of FIGS. 1-5;

FIG. 6b shows a cross-sectional view of the antenna arrangement of FIG. 6a along the line A-A′ of FIG. 6a on an enlarged scale.

### DESCRIPTION OF THE PREFERRED EMBODIMENT

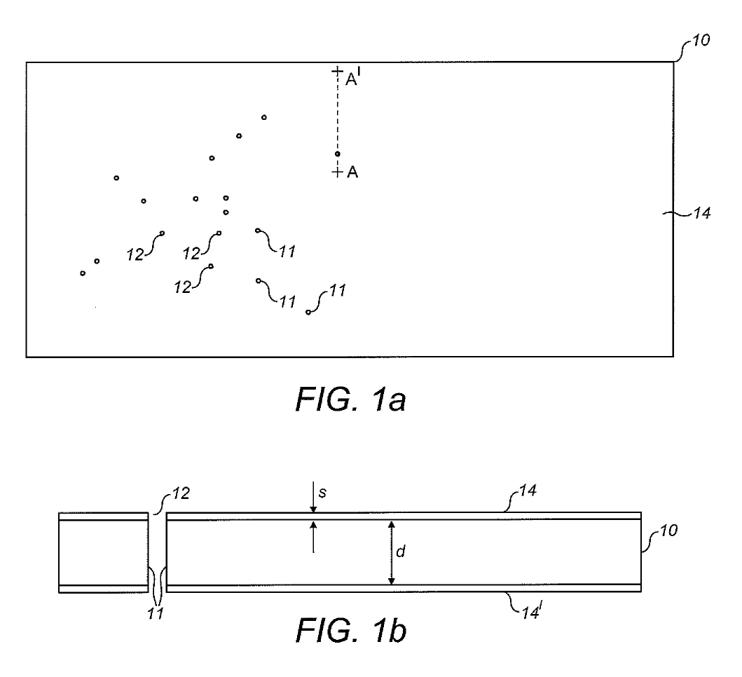

FIGS. 1 to 6 show an antenna arrangement of the invention in different stages of its production.

FIG. 1a shows a plan view of the upper side of a printed circuit board 10, which comprises an upper side and a lower side, on which in each case a copper layer 14, 14′ has been applied. FIG. 1a shows holes 12 for interconnections 22 (vias) between circuit parts on the upper side and circuit parts on the lower side of the printed circuit board 10. The via holes 12 may be produced, for example by a drilling or milling process. Side walls 11 of the printed circuit board 10 define the via holes 12.

FIG. 1b shows the printed circuit board 10 of FIG. 1a in a cross-section along the line A-A′ of FIG. 1a. In addition to a via hole 12, the copper layers 14, 14′ can also be seen, which are applied in each case to the upper side and the lower side of the printed circuit board 10. In FIG. 1b and also in the remaining cross-sectional representations, the thickness s of the copper layers 14, 14′ is shown to be excessively large compared to the thickness d of the printed circuit board 10. The thickness d of the printed circuit board 10 may be, for example about 1.5 mm and the thickness s of the copper layers 14, 14′ in each case about 50 μm.

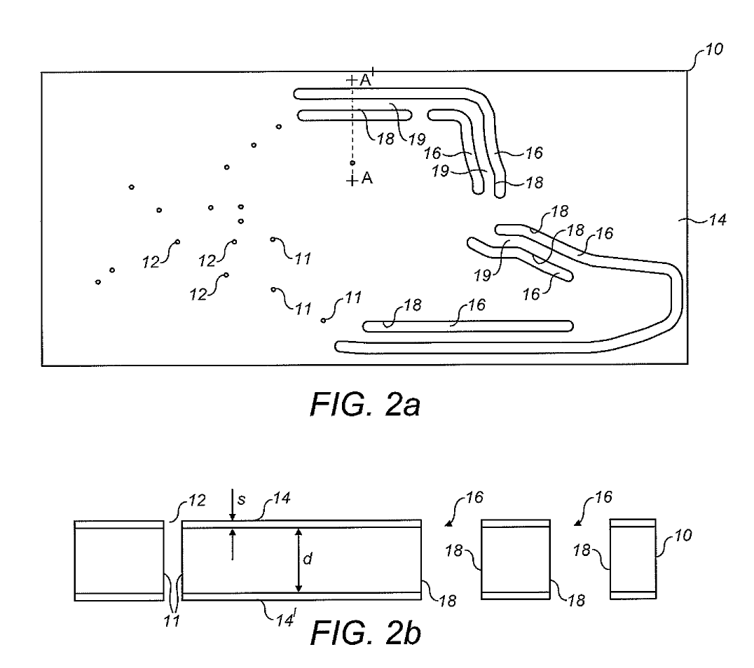

FIG. 2a shows the printed circuit board 10 of FIG. 1 after elongated holes 16 have been generated in the printed circuit board 10. The elongated holes 16 run along required antenna conductor tracks and are defined in each case in annular manner by a narrow side 18 of the printed circuit board 10. In some sections in each case two elongated holes 16 run parallel to one another on opposite sides of an antenna conductor track so that in each case an elongated self-supporting bar 19 of the printed circuit board 10 is defined by two adjacent elongated holes 16, which printed circuit board 10 may support an upper-side and lower-side antenna section 24, 24′.

In the present exemplary embodiment, the elongated holes 16 are generated by a milling process. The elongated holes 16 are milled vertically to the upper side and lower side of the printed circuit board 10 so that the narrow sides 18 defining the elongated holes 16 and the upper side or lower side of the printed circuit board 10 form essentially a right-angle. The drilling process for the via holes 12 and the milling process for the elongated holes 16 may be carried out in a common process step in the same machine.

After generating the via holes 12 and the elongated holes 16, the side walls 11 of the via holes 12 and the narrow sides 18 defined by the elongated holes 16 are coated with a conductive material, in the present exemplary embodiment with copper, by a deposition process.

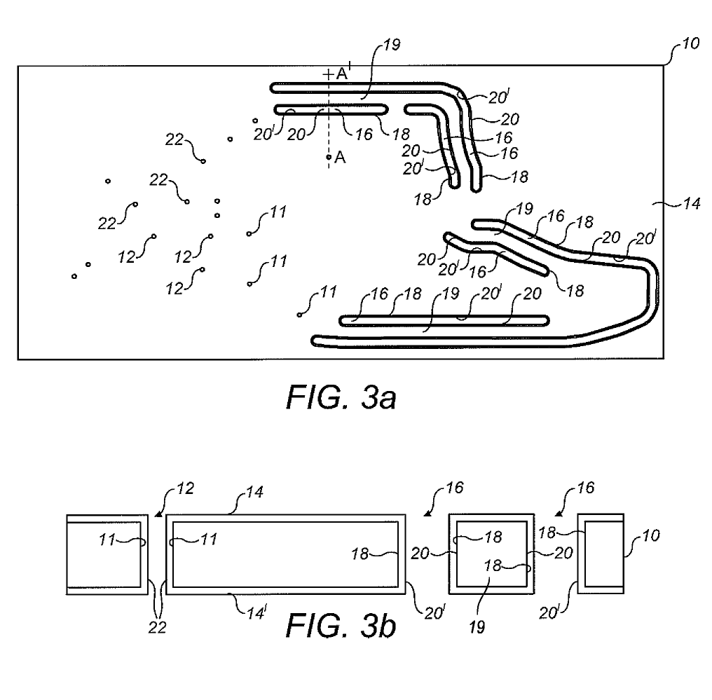

FIG. 3a shows a plan view of the arrangement of FIG. 2a after deposition, which may be effected in a manner known per se by galvanisation in a galvanic bath. The thickness of the deposited copper material may be, for example several 10 μm.

The copper material deposited on the narrow sides 18 forms firstly narrow-sided antenna sections 20 and secondly undesirable or not required copper material 20′, namely in the regions of the narrow sides 18 defining the elongated holes 16 and which are facing away from the required narrow-sided antenna section 20. In addition, the copper deposited in the via holes 12 forms the interconnections 22 (vias).

FIG. 3b shows that the cross-section of a self-supporting printed circuit board bar 19 is surrounded all around by conductive material, namely by the copper layers 14, 14′ and the narrow-sided antenna sections 20. The conductive material 14, 14′, 20 surrounding the self-supporting bar 19 forms due to its geometry an antenna current path with increased conductivity.

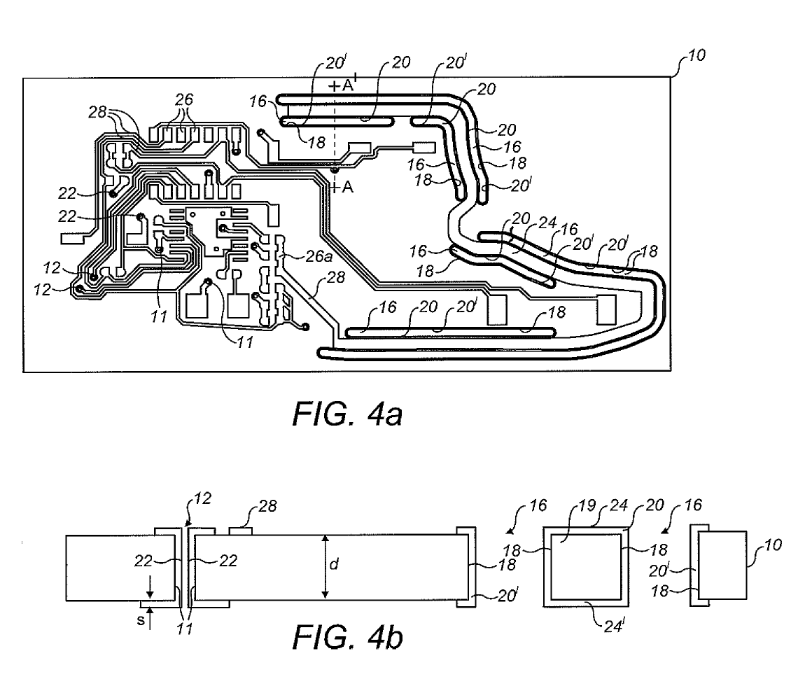

After deposition of the conductive material, the copper layer 14 is structured in suitable manner on the upper side and the copper layer 14′ on the lower side of the printed circuit board 10, for example by an etching process known per se in order to provide electrically conductive antenna sections 24, 24′ on the upper side and the lower side of the printed circuit board 10 and electrical connection leads 28 and electrical connection surfaces 26 for circuit parts to be produced in addition to the antenna on the printed circuit board 10 (FIG. 4).

FIGS. 4a, b, c show the printed circuit board 10 after structuring of the copper layers 14, 14′. For better orientation, the view of the lower side of the printed circuit board 10 is shown in FIG. 4c from the perspective from the top, that is, from the upper side observed through the printed circuit board 10, so that it can be seen in simplified manner which elements on the upper side of the printed circuit board 10 are opposite which elements on the lower side of the printed circuit board 10 without the observer having to take into account the mirror-inverted perspective which is produced if the printed circuit board 10 is observed once from the top and once from the bottom.

As FIG. 4a shows, an approximately annular antenna section 24 is formed on the upper side of the printed circuit board 10 and which runs in some regions along the narrow sides 18 of the elongated holes 16 and thus is in electrical contact with the conductive material of the narrow-sided antenna sections 20 deposited on the narrow sides 18. An essentially identically designed antenna section 24′, which is likewise connected to the conductive material of the narrow-sided antenna section 20, is formed opposite the antenna section 24 on the lower side of the printed circuit board 10. The two antenna sections 24, 24′ on the upper side and the lower side are connected to one another via the narrow-sided antenna sections 20, as shown in FIG. 4b.

The antenna conductor tracks 24, 24′ on the upper side and lower side of the printed circuit board 10, together with the narrow-sided antenna sections 20, form an essentially annular antenna, which, in particular in the region of the self-supporting bars 19, has an increased conductivity due to the conductive material deposited on the narrow sides 18 and reduced dielectric losses due to the formation of the elongated holes 16 in the dielectric material of the printed circuit board 10.

FIG. 4a shows several electrical connection surfaces 26 generated in the structuring step and electrical connection leads 28. These connection surfaces 26 and connection leads 28 permit attachment of electronic components for the formation of an activation circuit for activation of the antenna on the printed circuit board 10. The antenna is connected to the activation circuit via the connection surface 26a and via a connection surface 26b located on the rear side of the printed circuit board 10 and which serves the circuit as a reference potential.

To form the activation circuit, electronic components, for example SMD components, may be attached in a manner known per se to the connection surfaces 26 and connected to one another via the electrical connection leads 28. As FIGS. 4a, b and c show, circuit parts are thus connected to one another on the upper side of the printed circuit board 10 by the interconnections 22 produced before the structuring process. Assembly of the components to form the activation circuit may be effected before or after a cut-to-size step following the structuring step or even between two part steps of the cut-to-size step. The cut-to-size step is illustrated below.

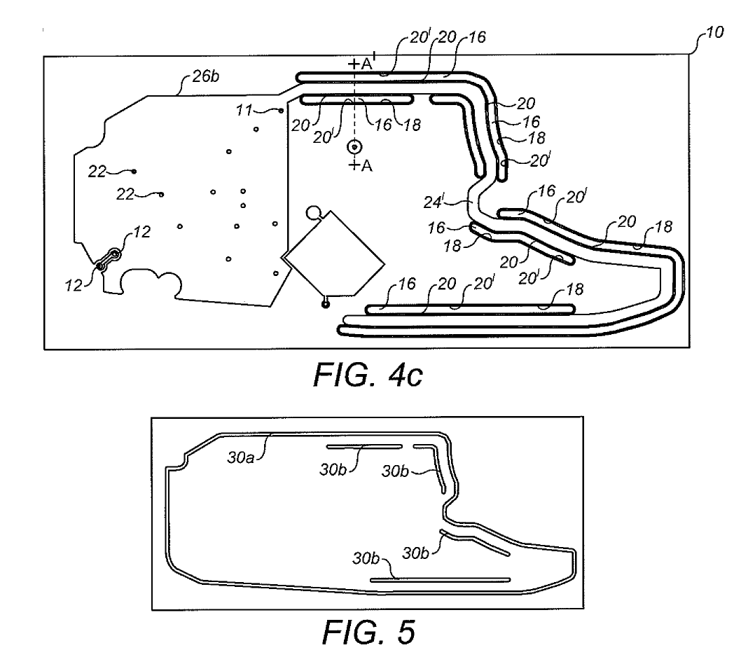

After structuring, the printed circuit board 10 is cut to the required size of the antenna arrangement. FIG. 5 shows schematically the cutting lines 30a, b, along which the printed circuit board 10 is cut to size. Due to the cutting line 30a, the outer contour of the printed circuit board 10 is defined so that the narrow-sided antenna sections 20 adjacent the cutting line 30a of the elongated holes 16 placed on the outside now form outer sides of the printed circuit board 10 and regions of the antenna sections 24, 24′ on the upper side and lower side directly adjoin the outer side of the printed circuit board 10. Electrically conductive material 20′ which is not necessary and excess printed circuit board material is thus removed.

Instead of cutting to size all around the outer contour of the printed circuit board 10, that is, according to a closed cutting line, such as the cutting line 30a, the outer contour of the printed circuit board 10 may also be cut to size in that printed circuit board material, which extends between an elongated hole 16 placed on the outside and an outer side of the printed circuit board 10, is cut out by two cuts guided between the outer side of the printed circuit board 10 and the elongated hole 16. In this case, the printed circuit board 10 may preferably be cut to size coarsely to an outer contour even before the structuring of the copper layers 14, 14′ and which is somewhat greater than its final dimension, so that thin bars of the printed circuit board 10 remain which extend between the outer elongated holes 16 and the outer side of the printed circuit board 10. They are then cut out in a further cut-to-size step following structuring.

Undesirable deposited electrically conductive material 20′ is also removed at the elongated holes 16 lying on the inside by the cutting lines 30b. Printed circuit board material placed around the undesirable electrically conductive material 20′ is thus optionally also removed.

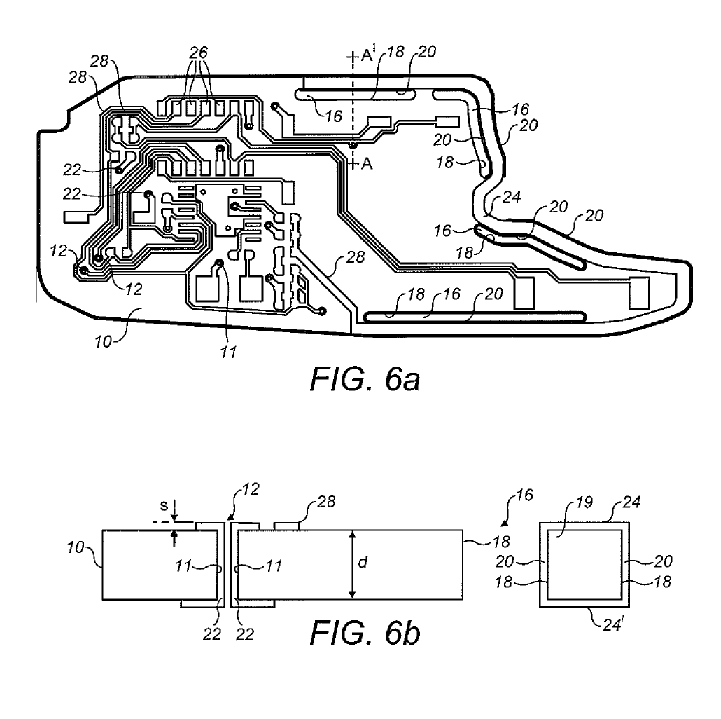

FIGS. 6a and b show the finished antenna arrangement after cutting-to-size. In this antenna arrangement, the electrical conductivity of the antenna is increased by the narrow-sided antenna sections 20, and the dielectric losses are reduced by the removal of dielectric material. By using outer narrow sides 18 of the printed circuit board 10 for narrow-sided sections 20 of the antenna, in addition a maximum antenna diameter is achieved with minimum space requirement of the antenna arrangement.

1. An antenna arrangement comprising a printed circuit board, which has an upper side and a lower side, and an antenna supported by the printed circuit board, in particular ring antenna, which comprises at least one electrically conductive antenna section which is arranged on a narrow side of the printed circuit board adjoining the upper side and/or the lower side.

2. The antenna arrangement of claim 1, wherein the narrow side extends from the upper side to the lower side of the printed circuit board.

3. The antenna arrangement of claim 1, wherein the narrow side defines a hole of the printed circuit board or forms an outer side of the printed circuit board.

4. The antenna arrangement of claim 1, wherein the narrow-sided antenna section is connected to an antenna section running on the upper side and/or to an antenna section running on the lower side.

5. The antenna arrangement of claim 1, wherein two narrow-sided antenna sections on opposite sides of an antenna section running on the upper side and/or of an antenna section running on the lower side are connected to the latter.

6. The antenna arrangement of claim 1, wherein the narrow-sided antenna section connects an antenna section arranged on the upper side of the printed circuit board to an antenna section arranged on the lower side of the printed circuit board.

7. The antenna arrangement of claim 1, wherein the narrow-sided antenna section electrically bridges an interruption of an antenna section running on the upper side or on the lower side of the printed circuit board.

8. A process for producing an antenna arrangement which comprises a printed circuit board with an upper side and a lower side and an antenna supported by the printed circuit board, in particular for producing an antenna arrangement according to one of the above claims, in which process for forming at least one antenna section, an electrically conductive material is applied to a narrow side of the printed circuit board which adjoins the upper side and/or the lower side.

9. The process of claim 8, wherein the narrow side of the printed circuit board is generated by removing printed circuit board material, in particular by the formation of a hole in the printed circuit board generated by means of a drilling or milling process.

10. The process of claim 9, wherein the removal of printed circuit board material for generating the narrow side is effected in a common process step with formation of holes for interconnections between circuit parts on the upper side and the lower side of the printed circuit board.

11. The process of claim 8, wherein the electrically conductive material is attached to the narrow side by a deposition process, in particular by means of a galvanic process.

12. The process of claim 11, wherein the deposition process, at the same time the narrow side and side walls, which define holes for interconnections between circuit parts on the upper side and the lower side of the printed circuit board, are coated with electrically conductive material.

13. The process of claim 8, wherein electrically conductive material attached to the narrow side and/or printed circuit board material which is adjoined thereto are removed in some regions, in particular by a milling process.

14. The process of claim 13, wherein the narrow side is generated by the formation of a hole in the printed circuit board and after metallisation of the narrow side, printed circuit board material is removed which extends between the hole and an outer side of the printed circuit board so that the narrow side itself becomes the outer side of the printed circuit board.

15. An antenna assembly comprising:
a electrically insulating substrate forming opposed upper and lower sides and a narrow side extending generally normally between said upper and lower sides; and
an antenna supported by the substrate, said antenna including at least one electrically conductive antenna section disposed on said narrow side adjoining the upper side and/or the lower side.

16. The antenna assembly of claim 15, wherein said antenna is a ring antenna.

17. The antenna assembly of claim 15, wherein said substrate comprises a printed circuit board.
